(19) United States
(12) Patent Application Publication
(10) Pub. No.: US 2023/0010741 A1
(43) Pub. Date: Jan. 12, 2023

(54) SEMICONDUCTOR-BASED SELECTIVE EMITTER FOR THERMOPHOTOVOLTAIC ENERGY CONVERSION AND METHOD FOR FABRICATING THE SAME

(71) Applicants: Liping Wang, Chandler, AZ (US); Rajagopalan Ramesh, Tempe, AZ (US); Qing Ni, Hefei (CN)

(72) Inventors: Liping Wang, Chandler, AZ (US); Rajagopalan Ramesh, Tempe, AZ (US); Qing Ni, Hefei (CN)

(73) Assignee: ARIZONA BOARD OF REGENTS ON BEHALF OF ARIZONA STATE UNIVERSITY, Scottsdale, AZ (US)

(21) Appl. No.: 17/859,987

(22) Filed: Jul. 7, 2022

Related U.S. Application Data
(60) Provisional application No. 63/219,821, filed on Jul. 8, 2021.

(51) Int. Cl. H02S 10/30; H01L 31/0216; H01L 31/028; H01L 31/056; H01L 31/18

(52) U.S. Cl. CPC H02S 10/30; H01L 31/02168; H01L 31/028; H01L 31/056; H01L 31/1808

(57) ABSTRACT

A selective emitter for thermophotovoltaic energy conversion and method for fabricating the same is disclosed. The selective emitter includes a germanium wafer, and a reflective layer deposited on a first side of the germanium wafer. The reflective layer includes tungsten. The selective emitter also includes an anti-reflective layer deposited on a second side of the germanium wafer opposite the first side. The anti-reflective layer includes Si₃N₄. The method for fabricating a selective emitter for thermophotovoltaic energy conversion includes deposing a reflective layer on a first side of a germanium wafer, and deposing an anti-reflective layer on a second side of the germanium wafer, the first side being opposite the second side. The germanium wafer may be undoped. The reflective layer may be sputtered onto the germanium wafer. The anti-reflective layer may be deposited on the germanium wafer using plasma-enhanced chemical vapor deposition.

### RELATED APPLICATIONS

This application claims the benefit of U.S. provisional patent application 63/219,821, filed Jul. 8, 2021 titled “Semiconductor-Based Selective Emitter for Thermophotovoltaic Energy Conversion,” the entirety of the disclosure of which is hereby incorporated by this reference.

### STATEMENT REGARDING FEDERALLY SPONSORED RESEARCH

This invention was made with government support under 1454698 awarded by the National Science Foundation and under FA9550-17-1-0080 awarded by the Air Force Office of Scientific Research. The government has certain rights in the invention.

### TECHNICAL FIELD

Aspects of this document relate generally to selective emitters for thermophotovoltaic energy conversion.

### BACKGROUND

Thermophotovoltaic (TPV) devices convert thermal radiation from a high-temperature emitter to electricity via a narrow-bandgap photovoltaic (PV) cell. Since the emitter can be heated by any kind of heat source (e.g., combustible fuel, solar energy, waste heat, etc.), TPV technology has a wide range of applications. The theoretical efficiency of the TPV system has the Carnot limit. However, due to the mismatch between the thermal radiation spectrum of the emitter and the absorption spectrum of the cell, conventional TPV systems have low electric power output and poor efficiency. To overcome this problem, much work has been carried out on spectrally selective emitters that emit photons with energy just above the bandgap of the PV cell. An ideal selective emitter should have an emissivity of one over a certain bandwidth just above the bandgap of the PV cell, and an emissivity of zero elsewhere. Spectrally selective PV cells have been shown to enhance TPV efficiency exceeding 30% at 1455 K by recycling the unused photons to the emitter.

Previous efforts have shown that the spectrally selective emitters can be achieved and tuned using photonic crystals and metamaterial structures. However, the complex geometries and the difficult fabrication processes have prevented any significant low-cost fabrication. Furthermore, the high temperature stability of these nanostructures after long-term practical operation is another big concern. Difficult fabrication and limited operational lifespan make these conventional spectrally selective emitters too expensive for practical use.

### SUMMARY

According to one aspect, a selective emitter for thermophotovoltaic energy conversion includes a germanium wafer, the germanium wafer being undoped and less than 500 μm thick. The emitter also includes a reflective layer deposed on a first side of the germanium wafer, the reflective layer composed of tungsten and being at least 200 nm thick. The emitter also includes an anti-reflective layer deposed on a second side of the germanium wafer opposite the first side, the anti-reflective layer including Si₃N₄ and being at least 150 nm thick.

Particular embodiments may comprise one or more of the following features. The tungsten of the reflective layer may be sputtered onto the germanium wafer. The Si₃N₄ of the anti-reflective layer may be deposited on the germanium wafer using plasma-enhanced chemical vapor deposition.

According to another aspect of the disclosure, a selective emitter for thermophotovoltaic energy conversion includes a germanium wafer, and a reflective layer deposited on a first side of the germanium wafer. The reflective layer includes tungsten. The emitter also includes an anti-reflective layer deposited on a second side of the germanium wafer opposite the first side, the anti-reflective layer including Si₃N₄.

Particular embodiments may comprise one or more of the following features. The tungsten of the reflective layer may be sputtered onto the germanium wafer. The Si₃N₄ of the anti-reflective layer may be deposited on the germanium wafer using plasma-enhanced chemical vapor deposition. The germanium wafer may be undoped. The germanium wafer may be less than 500 μm thick. The reflective layer may be at least 200 nm thick. The anti-reflective layer may be at least 150 nm thick.

According to yet another aspect of the disclosure, a method for fabricating a selective emitter for thermophotovoltaic energy conversion includes deposing a reflective layer on a first side of a germanium wafer, and deposing an anti-reflective layer on a second side of the germanium wafer. The first side is opposite the second side.

Particular embodiments may comprise one or more of the following features. The germanium wafer may be undoped. The germanium wafer may be less than 500 μm thick. The reflective layer may include tungsten. The reflective layer may be at least 200 nm thick. The anti-reflective layer may include Si₃N₄. The anti-reflective layer may be at least 150 nm thick. Deposing the reflective layer may include sputtering the reflective layer onto the germanium wafer. The anti-reflective layer may be deposed on the germanium wafer using plasma-enhanced chemical vapor deposition.

Aspects and applications of the disclosure presented here are described below in the drawings and detailed description. Unless specifically noted, it is intended that the words and phrases in the specification and the claims be given their plain, ordinary, and accustomed meaning to those of ordinary skill in the applicable arts. The inventors are fully aware that they can be their own lexicographers if desired. The inventors expressly elect, as their own lexicographers, to use only the plain and ordinary meaning of terms in the specification and claims unless they clearly state otherwise and then further, expressly set forth the “special” definition of that term and explain how it differs from the plain and ordinary meaning. Absent such clear statements of intent to apply a “special” definition, it is the inventors' intent and desire that the simple, plain and ordinary meaning to the terms be applied to the interpretation of the specification and claims.

The inventors are also aware of the normal precepts of English grammar. Thus, if a noun, term, or phrase is intended to be further characterized, specified, or narrowed in some way, then such noun, term, or phrase will expressly include additional adjectives, descriptive terms, or other modifiers in accordance with the normal precepts of English grammar. Absent the use of such adjectives, descriptive terms, or modifiers, it is the intent that such nouns, terms, or phrases be given their plain, and ordinary English meaning to those skilled in the applicable arts as set forth above.

Further, the inventors are fully informed of the standards and application of the special provisions of 35 U.S.C. § 112(f). Thus, the use of the words “function,” “means” or “step” in the Detailed Description or Description of the Drawings or claims is not intended to somehow indicate a desire to invoke the special provisions of 35 U.S.C. § 112(f), to define the invention. To the contrary, if the provisions of 35 U.S.C. § 112(f) are sought to be invoked to define the inventions, the claims will specifically and expressly state the exact phrases “means for” or “step for”, and will also recite the word “function” (i.e., will state “means for performing the function of [insert function]”), without also reciting in such phrases any structure, material or act in support of the function. Thus, even when the claims recite a “means for performing the function of . . . ” or “step for performing the function of . . . ,” if the claims also recite any structure, material or acts in support of that means or step, or that perform the recited function, then it is the clear intention of the inventors not to invoke the provisions of 35 U.S.C. § 112(f). Moreover, even if the provisions of 35 U.S.C. § 112(f) are invoked to define the claimed aspects, it is intended that these aspects not be limited only to the specific structure, material or acts that are described in the preferred embodiments, but in addition, include any and all structures, materials or acts that perform the claimed function as described in alternative embodiments or forms of the disclosure, or that are well known present or later-developed, equivalent structures, material or acts for performing the claimed function.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

The disclosure will hereinafter be described in conjunction with the appended drawings, where like designations denote like elements, and:

FIG. 1 is a side view of a selective emitter for thermophotovoltaic energy conversion;

FIG. 2 is a process flow of a method for fabricating a selective emitter;

FIG. 3A is a schematic view of a selective emitter and the resulting wave propagation;

FIG. 3B shows the theoretical normal spectral emittance of a selective emitter;

FIGS. 3C and 3D show the theoretical spectral emittance of a selective emitter at different incident angles for TM and TE waves, respectively;

FIGS. 4A and 4B show the spectral emittance of a selective emitter for different wavelengths and temperatures, respectively; and

FIGS. 5A through 5D are various measures of performance of a selective emitter paired with a photovoltaic cell.

### DETAILED DESCRIPTION

This disclosure, its aspects and implementations, are not limited to the specific material types, components, methods, or other examples disclosed herein. Many additional material types, components, methods, and procedures known in the art are contemplated for use with particular implementations from this disclosure. Accordingly, for example, although particular implementations are disclosed, such implementations and implementing components may comprise any components, models, types, materials, versions, quantities, and/or the like as is known in the art for such systems and implementing components, consistent with the intended operation.

The word “exemplary,” “example,” or various forms thereof are used herein to mean serving as an example, instance, or illustration. Any aspect or design described herein as “exemplary” or as an “example” is not necessarily to be construed as preferred or advantageous over other aspects or designs. Furthermore, examples are provided solely for purposes of clarity and understanding and are not meant to limit or restrict the disclosed subject matter or relevant portions of this disclosure in any manner. It is to be appreciated that a myriad of additional or alternate examples of varying scope could have been presented, but have been omitted for purposes of brevity.

While this disclosure includes a number of embodiments in many different forms, there is shown in the drawings and will herein be described in detail particular embodiments with the understanding that the present disclosure is to be considered as an exemplification of the principles of the disclosed methods and systems, and is not intended to limit the broad aspect of the disclosed concepts to the embodiments illustrated.

Thermophotovoltaic (TPV) devices convert thermal radiation from a high-temperature emitter to electricity via a narrow-bandgap photovoltaic (PV) cell. Since the emitter can be heated by any kind of heat source (e.g., combustible fuel, solar energy, waste heat, etc.), TPV technology has a wide range of applications. The theoretical efficiency of the TPV system has the Carnot limit. However, due to the mismatch between the thermal radiation spectrum of the emitter and the absorption spectrum of the cell, conventional TPV systems have low electric power output and poor efficiency. To overcome this problem, much work has been carried out on spectrally selective emitters that emit photons with energy just above the bandgap of the PV cell. An ideal selective emitter should have an emissivity of one over a certain bandwidth just above the bandgap of the PV cell, and an emissivity of zero elsewhere. Spectrally selective PV cells have been shown to enhance TPV efficiency exceeding 30% at 1455 K by recycling the unused photons to the emitter.

Previous efforts have shown that the spectrally selective emitters can be achieved and tuned using photonic crystals and metamaterial structures. However, the complex geometries and the difficult fabrication processes have prevented any significant low-cost fabrication. Furthermore, the high temperature stability of these nanostructures after long-term practical operation is another big concern. Difficult fabrication and limited operational lifespan make these conventional spectrally selective emitters too expensive for practical use.

Spectrally selective emitters can also be realized by multilayer structures based on the anti-reflection effect or cavity resonance, which are potentially much easier to fabricate on a large scale. Based on Kirchhoff's law of thermal radiation that absorptivity equals emissivity at every wavelength in thermal equilibrium, spectrally selective absorbers may also serve as spectrally selective emitters. A previous effort led to a multilayer selective solar absorber which had good spectral selectivity behavior and high temperature stability. However, the cutoff wavelength (i.e., the transition between the high emittance above the bandgap and the low emittance below the bandgap) was not sharp, still resulting in undesirable photons below the bandgap.

Contemplated herein is a semiconductor-based selective emitter for thermophotovoltaic energy conversion (hereinafter “TPV emitter”, “selective emitter”, or “emitter”). While most conventional semiconductor-based selective absorber/emitters have been built around silicon, the TPV emitter contemplated herein makes use of germanium, which has a lower energy bandgap (0.67 eV) and is well adapted for TPV application. Specifically, the contemplated TPV emitter is a germanium (Ge) semiconductor sandwiched between a reflective layer and an anti-reflective layer. In some embodiments, the contemplated emitter exhibits a nearly two-fold increase in TPV efficiency compared to a black emitter control.

The contemplated semiconductor-based selective emitter is well adapted for TPV applications since the bandgap edge provides a sharp cutoff wavelength and nearly zero sub-bandgap emission. This leads to a much more efficient device, eliminating undesirable photon emission below the bandgap and substantially limiting photon emission to the narrow bandgap absorption range of a PV cell.

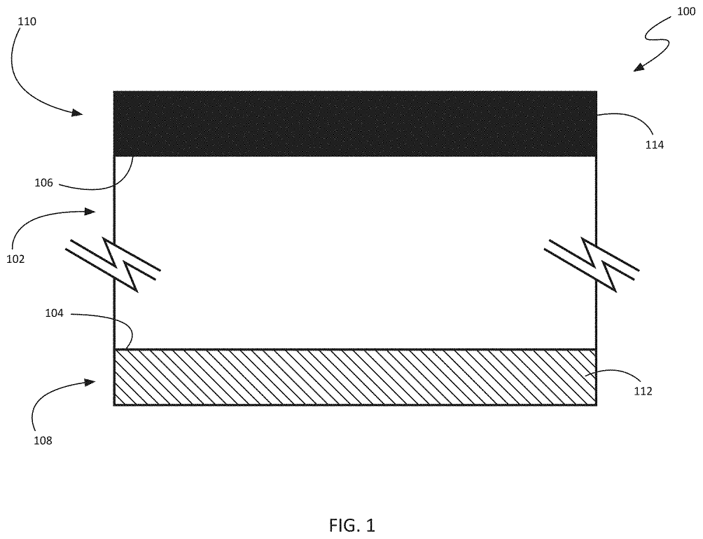

FIG. 1 is a side view of a non-limiting example of a semiconductor-based selective emitter 100 for thermophotovoltaic energy conversion. As shown, the emitter 100 comprises a germanium (Ge) wafer 102 102 having a first side 104 and a second side 106 opposite the first side 104. The emitter 100 further comprises a reflective layer 108 deposited on or otherwise coupled to the first side 104 of the Ge wafer 102 102, and an anti-reflective layer 110 deposited on or otherwise coupled to the second side 106. According to various embodiments, the reflective 108 and anti-reflective 110 layers could also be described as films or coatings; in some embodiments, these layers are one or more orders of magnitude thinner than the Ge wafer 102 acting as a substrate.

The reflective layer 108 (or rear layer) is used to ensure the opaqueness of the structure with high reflectivity below the bandgap of Ge. According to various embodiments, the reflective layer 108 may be made of tungsten 112, which is well-adapted for acting as a reflector below the bandgap of Ge. The anti-reflective layer 110 (e.g., the PV-facing side of the emitter 100) is used to reduce in-band reflection and enhance absorption or emission. According to various embodiments, the anti-reflective layer 110 may be composed of Si₃N₄ 114.

It should be noted that while much of the discussion below will be done in the context of a specific, non-limiting embodiment of the selective emitter 100 having a reflective layer 108 comprising tungsten 112 and an anti-reflective layer 110 comprising Si₃N₄ 114, other embodiments of the contemplated emitter 100 may employ other materials suitable for the anticipated operating temperatures. For example, in one embodiment, the reflective layer 108 hay comprise nickel. In other embodiments, the anti-reflective layer 110 may comprise other refractory oxides such as Al₂O₃ and HfO₂.

According to various embodiments, the germanium wafer 102 may be undoped, which further simplifies the fabrication process. In other embodiments, the semi-conductor wafer of the contemplated emitter 100 may be doped. In some embodiments, the Ge wafer 102 may be 500 μm thick. In other embodiments, the Ge wafer 102 may be less than 500 μm thick. In still other embodiments, the Ge wafer 102 may be more than 500 μm thick.

In some embodiments, the reflective layer 108 may be 200 nm thick. In other embodiments, the reflective layer 108 may be less than 200 nm thick. In still other embodiments, the reflective layer 108 may be more than 200 nm thick. Furthermore, in some embodiments, the anti-reflective layer 110 may be 150 nm thick. In other embodiments, the anti-reflective layer 110 may be less than 150 nm thick. In still other embodiments, the anti-reflective layer 110 may be more than 150 nm thick.

The following discussion will be done in the context of a specific embodiment of the contemplated selective emitter 100 having a germanium wafer 102 that is 500 μm thick, a reflective layer 108 that is 200 nm thick and made of tungsten 112, and an anti-reflective layer 110 that is 150 nm thick and made of Si₃N₄ 114.

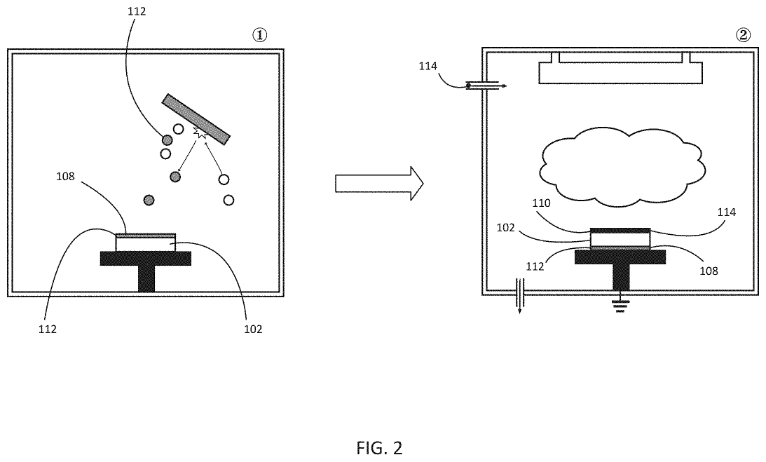

FIG. 2 is a process flow of a method for fabricating a non-limiting example of the contemplated selective emitter 100 discussed above. According to a specific embodiment, the Ge-based selective emitter 100 may be fabricated on a 500-μm-thick double-sided polished Ge wafer 102 (e.g., 50 Ω·cm from MTI Corporation, etc.) with the size of 1×1 cm². Before the deposition of layers (e.g., films, coatings, etc.), the Ge wafer 102 may be plasma cleaned.

First, a 200-nm reflective layer 108 of tungsten 112 is sputtered (e.g., with a Lesker PVD75 Sputter Coater, etc.) on the first side 104 of the Ge wafer 102 at a rate of 1 ks, under a vacuum pressure of 1×10⁻⁶ Torr. See ‘circle 1’. Next, a 150-nm anti-reflective layer 110 of Si₃N₄ 114 is deposited on the second side 106 of the Ge wafer 102 using a plasma-enhanced chemical vapor deposition (PECVD) method (e.g., with an Oxford Plasmalab100, etc.) at a rate of 290 Å/min under the temperature of 300° C. See ‘circle 2’. According to a specific embodiment, the root-mean-square surface roughness of the fabricated sample may be around 0.9 nm, as measured by an atomic force microscope. Those skilled in the art will recognize that the contemplated method for fabrication may be adapted for use in conjunction with other thin-film fabrication techniques known in the art.

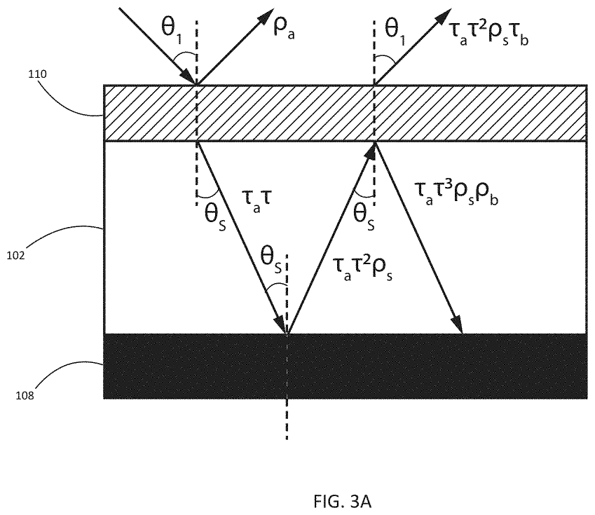

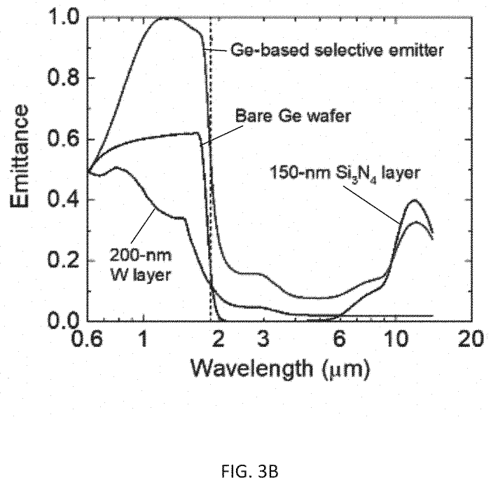

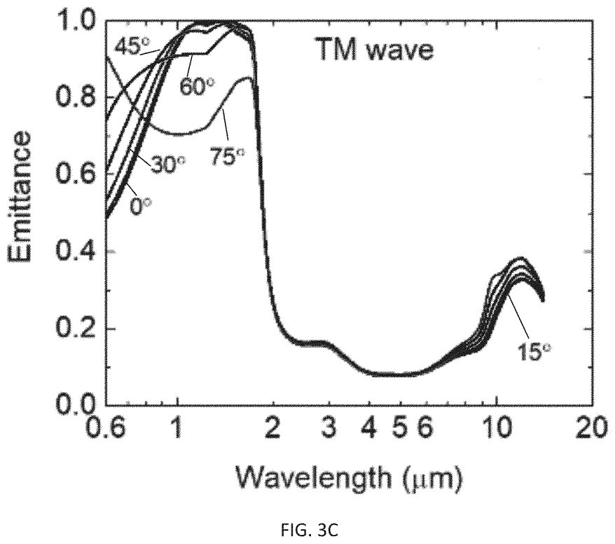

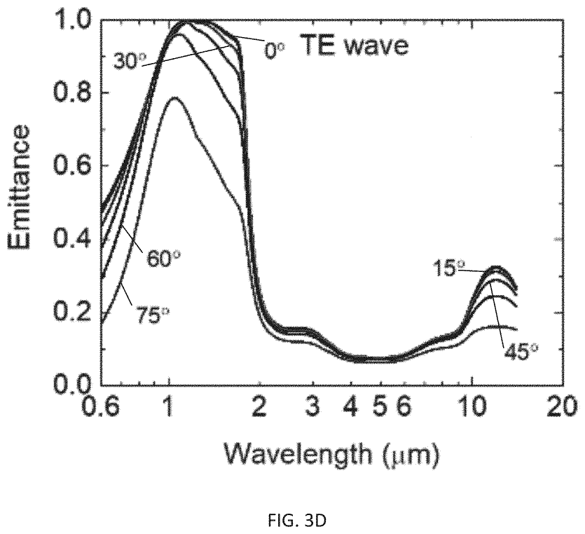

FIGS. 3A through 3D explore various properties of the specific embodiment of the selective emitter 100 discussed above. Specifically, FIG. 3A is a schematic of the contemplated Ge-based emitter 100 and the resulting wave propagation. FIG. 3B shows the theoretical normal spectral emittance of the specific embodiment of the contemplated emitter 100. FIGS. 3C and 3D show the theoretical spectral emittance of that same embodiment of the selective emitter 100 at different incident angles for TM waves (i.e., FIG. 3C) and TE waves (i.e., FIG. 3D).

According to Kirchhoff's law, the spectral directional emittance is equal to the spectral directional absorptance as 1−R′_{λ} from energy balance with zero transmittance due to the opaque reflective layer 108 of tungsten 112. As shown in FIG. 3A, ρₐ or ρ_{B} respectively represent the reflectivity of the thin Si₃N₄ 114 layer for rays originating from air or from the Ge wafer 102, and τₐ or τ_{b} are the corresponding transmissivity. ρₛ represents the reflectivity of the tungsten 112 layer for rays originating from the Ge wafer 102.

It should be noted that the spectral directional reflectivity and transmissivity shown in FIG. 3 is calculated using the thin-film optics method for the anti-reflective layer 110 of Si₃N₄ 114 and the reflective layer 108 of tungsten 112, separately. The light propagation inside the incoherent thick Ge wafer 102 is taken into consideration using the ray-tracing method, and consequently the spectral directional reflectance of the proposed Ge-based selective emitter 100 with front (i.e., anti-reflective) and backside (i.e., reflective) layers can be calculated as:

R′_{λ}=ρₐ+ρₛρₐ²ρ²/(1−ρₛρ_{b}τ²)

where τ=exp (−4πκₛdₛ/λ cos θₛ) is the internal transmissivity of the Ge wafer 102 with extinction coefficient κₛ, thickness dₛ, free-space wavelength λ, and refraction angle θₛ inside the Ge substrate calculated from incident angle θ₁ with Snell's law.

FIG. 3B shows the theoretical spectral emittance of the contemplated selective emitter 100. For comparison, the simulated emittance spectra of a 150-nm Si₃N₄ 114 layer, 200-nm tungsten 112 film, and 500-μm bare undoped Ge wafer 102, are also shown in the figure where the dash line represents the Ge bandgap at 1.85 μm wavelength (i.e., 0.67 eV). As shown, undoped Ge has almost zero sub-bandgap emission, with around 0.6 in-band emittance due to bandgap absorption. With the anti-reflective layer 110 of Si₃N₄ 114, the in-band emittance of the Ge-based selective emitter 100 is significantly enhanced, reaching unity at a wavelength of 1.3 μm, right above the bandgap. Right below the bandgap, the emittance sharply drops to roughly 0.1 due to the absorption of the lossy tungsten 112 layer. At longer wavelengths beyond 10 μm, the emittance increases to approximately 0.3 because of strong phonon absorption of Si₃N₄ 114.

FIGS. 3C and 3D respectively show the theoretical spectral emittance of the emitter 100 at different angles for transverse-magnetic (TM) and -electric (TE) polarized waves. It can be seen that at the wavelength below the bandgap, the emittance slightly increases with the incident angle for TM waves at first, and then decreases at large incident angle, which is due to the Brewster effect. For non-absorbing or lightly absorbing materials, reflectance at TM waves could decrease to minimum at a particular incidence angle, namely the Brewster angle.

According to various embodiments, the Brewster angle is about 75° for the undoped Ge wafer 102 used in the emitter 100, calculated by θ=tan⁻¹(n₂/n₁), where n₂ and n₁ represent the refractive index of Ge and air, respectively. The reflectance at TM waves decreases with the incident angle from 0° to 75°, which explains the trend of emittance shown in FIG. 3C. For TE waves, the emittance decreases monotonically with the incident angle, which means the reflectance increases monotonically with the incident angle. According to various embodiments, the spectral emittance of the contemplated structure is insensitive to the incident angles at small incident angles, indicating that the emitter 100 has diffuse emission behavior.

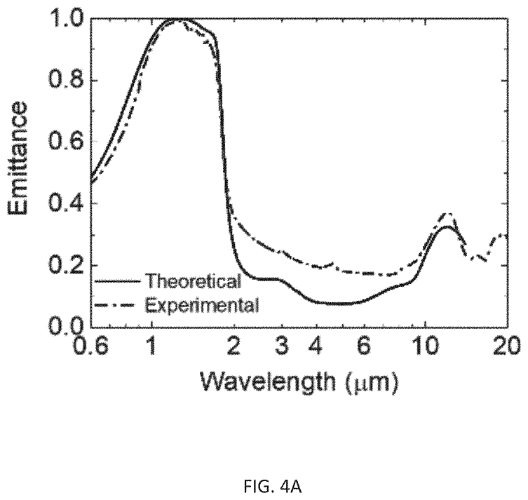

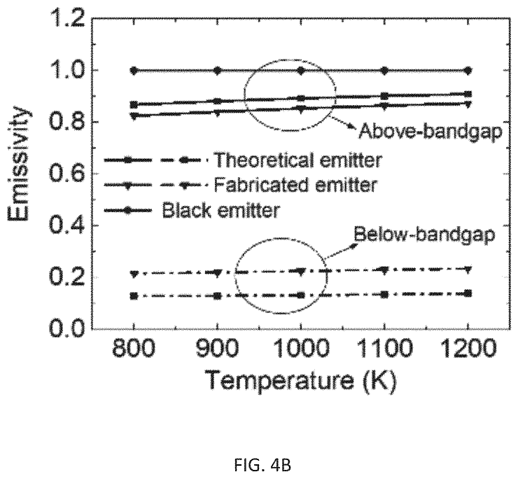

FIGS. 4A and 4B show the spectral emittance of a non-limiting example of the specific embodiment of the selective emitter 100 for different wavelengths and temperatures, respectively. The spectral normal emittance of the emitter 100 can be obtained by one minus spectral normal reflectance, as shown in FIG. 4A. It has been observed that the measured spectral emittance of this specific embodiment agrees well with the simulated one above the bandgap. Below the bandgap, the measured result is around 5% higher than the theoretical one, probably caused by the higher loss of the sputtered tungsten 112 film due to grains and slightly oxidation that leads to different optical constants of tungsten 112.

To evaluate the spectral selectivity of the contemplated emitter 100, the spectrally averaged emittance was calculated for above-bandgap spectrum ε̅_{above} and below-bandgap spectrum ε̅_{below} as:

ε̅_{above}=∫₀^{λ}^{_{ge}}ε_{λ}E_{b,λ}(T)dλ/∫₀^{λ}^{_{ge}}E_{b,λ}(T)dλ

ε̅_{below}=∫_{λ}_{_{ge}}^{∞}ε_{λ}E_{b,λ}(T)dλ/∫_{λ}_{_{ge}}^{∞}E_{b,λ}(T)dλ

where λ_{ge}=1.85 μm is the bandgap wavelength of Ge,

$${E}_{b , λ} ( T ) = 2 π {hc}_{0}^{2} / {λ}^{5} [ exp ( \frac{{hc}_{0}}{λ {K}_{B} T} ) - 1 ]$$

is the blackbody spectral emissive power with Plank's constant h, the speed of light in vacuum co, Boltzmann constant k_{B}, and absolute temperature T. FIG. 4B shows ε̅_{above} and ε̅_{below} at different temperatures for both theoretical Ge-based selective emitter 100 and a fabricated sample. It can be seen that both ε̅_{above} and ε̅_{below} of the theoretical Ge-based selective emitter 100 barely change with the temperature between 800 K and 1200 K. The same trend is shown for the fabricated sample. For the theoretical Ge-based selective emitter 100, the above-bandgap averaged emittance ε̅_{above} is 0.91 while the below-bandgap averaged emittance ε̅_{below} is 0.14 at 1200 K, according to various embodiments. In comparison, a black emitter has the emittance of 1 for the whole spectrum. Therefore, the contemplated Ge-based selective emitter 100 demonstrates good spectral selectivity.

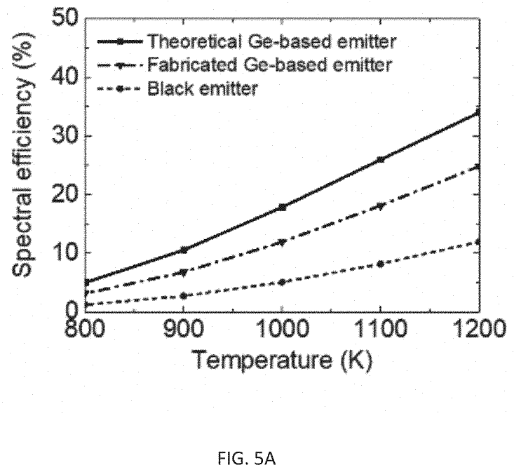

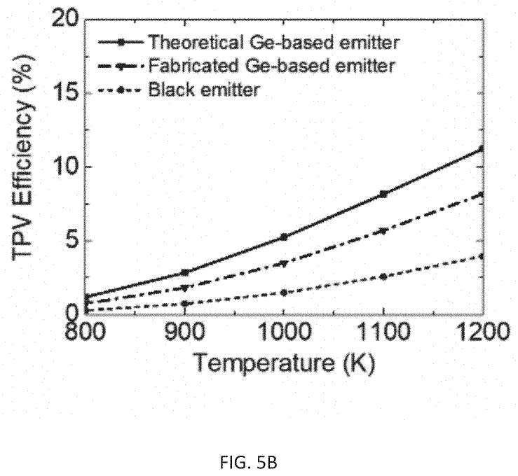

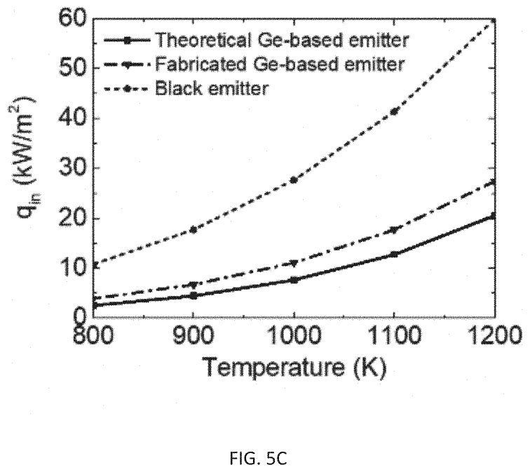

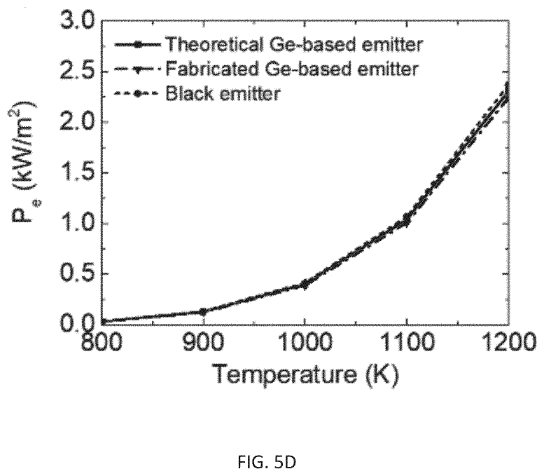

FIGS. 5A through 5D are various measures of performance of a non-limiting example of the specific embodiment of the selective emitter 100 discussed above, paired with a photovoltaic cell. Specifically, FIGS. 5A through 5D show the spectral efficiency (i.e., FIG. 5A), the TPV efficiency (i.e., FIG. 5B), the net radiative heat flux (i.e., FIG. 5C), and the output power (i.e., FIG. 5D) at temperatures ranging from 800 K to 1200 K with a theoretical Ge-based emitter 100, a fabricated Ge-based emitter 100, and black emitter, each paired with a GaSb cell.

According to various embodiments, the spectral efficiency can be defined as the percentage of the photons from the emitter 100 absorbed by the PV cell:

ƒ_{spectral}=∫₀^{λ}^{_{ge}}q_{e-c,λ}dλ/∫₀^{∞}q_{e-c,λ}dλ

where λ_{gc} is the bandgap wavelength of the PV cell,

$${q}_{e - c , λ} = \frac{{E}_{be , λ} ( {T}_{e} ) - {E}_{bc , λ} ( {T}_{c} )}{1 / {ε}_{e , λ} + 1 / {ε}_{c , λ} - 1}$$

is the spectral net radiative heat flux between the emitter and the cell with a view factor of 1, and the subscript e(c) represents the emitter (cell). ε_{e,λ} is the spectral emissivity of the emitter and ε_{c,λ} is the spectral emittance (or absorptance) of the PV cell, both of which are assumed to be diffuse. Tₑ and T_{c} are respectively the emitter temperature and the cell temperature.

FIG. 5A shows the spectral efficiency of the theoretical Ge-based selective emitter 100 at different temperatures. For comparison, the spectral efficiencies of a fabricated embodiment and a black emitter (ε_{e,λ}=1) are also shown. According to various embodiments, the spectral efficiency will increase with the emitter 100 temperature, which is because the thermal radiation spectrum shifts to lower wavelengths as the temperature increases, thus increasing the percentage of the photons with energies above the bandgap of the PV cell.

It should be noted that the theoretical Ge-based selective emitter 100 has higher spectral efficiency than the fabricated embodiment due to its lower sub-bandgap emittance. The contemplated Ge-based selective emitter 100 has higher spectral efficiency than a black emitter. At a temperature of 1200 K, the spectral efficiency of the theoretical Ge-based selective emitter 100 can achieve 34.0%, while that of a black emitter is only 12.0%.

To discuss the performance of the contemplated Ge-based selective emitter, the TPV efficiency ƒ can be calculated by

ƒ=Pₑ/qᵢₙ

where Pₑ=J_{sc}V_{oc}FF is the maximum output electric power density produced by the PV cell.

$${J}_{sc} = {\int }_{0}^{\frac{{hc}_{0}}{{E}_{g}}} \frac{e λ}{{hc}_{0}} {η}_{IQE , λ} {q}_{e - c , λ} d λ ( A / {cm}^{2} )$$

is the short-circuit current density. Note that E_{g} is the bandgap of the PV cell, e is an elementary charge, and ƒ_{IQE,λ} is the internal quantum efficiency of the PV cell. V_{oc}=(k_{B}T_{c}/e)ln(J_{sc}/J₀+1) is the open-circuit voltage (V), in which J₀ is the dark current calculated by J₀=e[nᵢ²Dₕ/(LₕN_{D})+nᵢ²Dₑ/(LₑN_{A})]. nᵢ is the intrinsic carrier concentration of the semiconductor, N_{D} and N_{A} are respectively the donor concentration and acceptor concentration, Dₕ and Dₑ are respectively the hole diffusion coefficient and electron diffusion coefficient, and Lₕ and Lₑ are respectively the hole and electron diffusion length. FF is the filling factor calculated by FF=(1−1/y)(1−ln y/y), in which y=ln(J_{sc}/J₀). gᵢₙ=∫₀^{∞}q_{e-c,λ}dλ is the net radiative heat flux between the emitter 100 and the cell with the same area.

FIGS. 5B, 5C, and 5D respectively predict the TPV efficiency, the net radiative heat flux between the emitter 100 and the PV cell, and the output power for the TPV system using the contemplated selective emitter 100 paired with a GaSb cell. For comparison, the results using a black emitter are also shown. With a black emitter at temperatures from 800 K to 1200 K, the TPV efficiency ranges from 0.3% to 4.0%.

With the fabricated Ge-based selective emitter 100 sample, the TPV efficiency was improved ranging from 0.8% to 8.2%, which is due to the good spectral selectivity of the Ge-based selective emitter 100 with low emittance below the bandgap, thus reducing the net radiative heat flux with almost the same power output.

With a theoretical Ge-based selective emitter 100, the TPV efficiency could be further improved, ranging from 1.2% to 11.2%. This is due to its lower sub-bandgap emittance, thus further reducing the net radiative heat flux. Note that these three emitters produce similar Pₑ below 1000 K.

As the emitter 100 temperature increases, the black emitter will surpass the contemplated Ge-based selective emitter 100. Pₑ depends on the net radiative heat flux above the bandgap of the cell. At low temperatures, the emissive power from the contemplated emitter 100 at short wavelengths (i.e., above the bandgap) is low, which causes similar power from these three emitter 100s.

As the temperature increases, the thermal emission spectrum shifts to shorter wavelengths. The black emitter has the highest emittance, resulting in the highest net radiative heat flux above the bandgap, thus producing the highest output power. As shown, this specific, fabricated Ge-based selective emitter 100 embodiment has the lowest emittance, resulting in the lowest net radiative heat flux above the bandgap and therefore producing the lowest power. In particular, at an emitter 100 temperature of 1200 K, the contemplated Ge-based selective emitter 100 can achieve a TPV efficiency of 11.2%, and an output power of 2.3 kW/m², according to various embodiments.

Where the above examples, embodiments and implementations reference examples, it should be understood by those of ordinary skill in the art that other materials and fabrication methods could be intermixed or substituted with those provided. In places where the description above refers to particular embodiments of a selective emitter for thermophotovoltaic energy conversion and method for fabricating the same, it should be readily apparent that a number of modifications may be made without departing from the spirit thereof and that these embodiments and implementations may be applied to other selective emitters and fabrication methods as well. Accordingly, the disclosed subject matter is intended to embrace all such alterations, modifications and variations that fall within the spirit and scope of the disclosure and the knowledge of one of ordinary skill in the art.

What is claimed is:

1. A selective emitter for thermophotovoltaic energy conversion, comprising:
a germanium wafer, the germanium wafer being undoped and less than 500 μm thick;
a reflective layer deposed on a first side of the germanium wafer, the reflective layer composed of tungsten and being at least 200 nm thick; and
an anti-reflective layer deposed on a second side of the germanium wafer opposite the first side, the anti-reflective layer comprising Si₃N₄ and being at least 150 nm thick.

2. The selective emitter of claim 1, wherein the tungsten of the reflective layer is sputtered onto the germanium wafer.

3. The selective emitter of claim 1, wherein the Si₃N₄ of the anti-reflective layer is deposited on the germanium wafer using plasma-enhanced chemical vapor deposition.

4. A selective emitter for thermophotovoltaic energy conversion, comprising:
a germanium wafer;
a reflective layer deposited on a first side of the germanium wafer, the reflective layer comprising tungsten; and
an anti-reflective layer deposited on a second side of the germanium wafer opposite the first side, the anti-reflective layer comprising Si₃N₄.

5. The selective emitter of claim 4, wherein the tungsten of the reflective layer is sputtered onto the germanium wafer.

6. The selective emitter of claim 4, wherein the Si₃N₄ of the anti-reflective layer is deposited on the germanium wafer using plasma-enhanced chemical vapor deposition.

7. The selective emitter of claim 4, wherein the germanium wafer is undoped.

8. The selective emitter of claim 4, wherein the germanium wafer is less than 500 μm thick.

9. The selective emitter of claim 4, wherein the reflective layer is at least 200 nm thick.

10. The selective emitter of claim 4, wherein the anti-reflective layer is at least 150 nm thick.

11. A method for fabricating a selective emitter for thermophotovoltaic energy conversion, comprising:
deposing a reflective layer on a first side of a germanium wafer; and
deposing an anti-reflective layer on a second side of the germanium wafer, the first side being opposite the second side.

12. The method of claim 11, wherein the germanium wafer is undoped.

13. The method of claim 11, wherein the germanium wafer is less than 500 μm thick.

14. The method of claim 11, wherein the reflective layer comprises tungsten.

15. The method of claim 11, wherein the reflective layer is at least 200 nm thick.

16. The method of claim 11, wherein the anti-reflective layer comprises Si₃N₄.

17. The method of claim 11, wherein the anti-reflective layer is at least 150 nm thick.

18. The method of claim 11, wherein deposing the reflective layer comprises sputtering the reflective layer onto the germanium wafer.

19. The method of claim 11, wherein the anti-reflective layer is deposed on the germanium wafer using plasma-enhanced chemical vapor deposition.
